(19) United States
(12) Patent Application Publication
(10) Pub. No.: US 2019/0376609 A1
(43) Pub. Date: Dec. 12, 2019

(54) ACTUATOR

(71) Applicant: Moog Controls Limited, Tewkesbuy (GB)

(72) Inventors: Ian Brooks, Tewkesbury (GB); Paul Guerrier, Tewkesbury (GB)

(21) Appl. No.: 16/481,237

(22) PCT Filed: Jan. 26, 2018
(86) PCT No.: PCT/GB2018/050219

§ 371 Date: Jul. 26, 2019

(30) Foreign Application Priority Data
Jan. 27, 2017 (GB) 1701353.3

(51) Int. Cl. F16K 31/00; F16K 11/07; H01L 41/053; H01L 41/047; H01L 41/09

(52) U.S. Cl. CPC F16K 31/004; F16K 11/07; H01L 41/0973; H01L 41/0475; H01L 41/053

(57) ABSTRACT

An actuator including a housing, a piezo electric disc having a first side and a second side and defining an outer rim, an elastomeric seal, wherein the outer rim is received in the housing and the elastomeric seal engages the first side proximate the outer rim to seal the first side to the housing, the elastomeric seal engages the second side proximate the outer rim to seal the second side to the housing.

The present invention relates to actuators, in particular actuators for actuating hydraulic spool valves.

Spool valves are known wherein a spool can be moved within a housing of the spool valve in order to connect and/or isolate hydraulic passages within the housing. Various types of actuator can be used to move the spool.

In the proceedings of the ASME/BATH 2015 symposium on Fluid Power and Motion Control held on the 12-14 Oct. 2015 in Chicago, Ill., USA, a paper entitled “Design and Modelling of a Novel Servo Valve Actuated by a Piezoelectric Ring Bender”, was given. This shows an actuator for a spool valve, in particular the actuator includes a piezo electric device known as a “ring bender”. The ring bender is an annular piezo electric disc that becomes generally domed in a concave or convex fashion depending upon the applied voltage.

The present invention relates to improvements in respect of ring bender actuators e.g. of the above mentioned paper.

Thus, according to the present invention there is provided an actuator including
a housing,
a piezo electric disc having a first side and a second side and defining an outer rim,
an elastomeric seal,
wherein the outer rim is received in the housing and the elastomeric seal engages the first side proximate the outer rim to seal the first side to the housing, the elastomeric seal engages the second side proximate the outer rim to seal the second side to the housing.

According to another aspect of the present invention there is provided an actuator including
a housing,
a piezo electric disc having a first side and a second side defining an outer rim, an inner rim, and a disc plane,
the piezo electric disc being mounted proximate the outer rim in the housing for movement of the inner rim relative to the outer rim during actuation,
the actuator further including an actuator output defining a breather portion and an output element, the output element being fixedly connected to the breather portion at a coupling plane, the coupling plane being spaced apart from the disc plane,
the breather portion being fixedly connected to the piezo electric disc proximate the inner rim at the disc plane,
the breather portion having a plurality of holes to allow fluid to move from the first side to the second side and from the second side to the first side.

According to another aspect of the present invention there is provided an actuator including
a housing,
a piezo electric disc having a first side and a second side defining an outer rim, an inner rim, and a disc plane,
the piezo electric disc being mounted proximate the outer rim in the housing for movement of the inner rim relative to the outer rim during actuation,
a first connector having a first region engaging the piezo electric disc on the first side and a first portion for reacting against an output element, the first connector defining a first stiffness between the first region and the first portion,
a second connector having a second region engaging the piezo electric disc on the second side and a second portion for reacting against the output element, the second connector defining a second stiffness between the second region and the second portion,
the first portion being spaced from the second portion, and
the first stiffness being different from the second stiffness, and
an output element connecting the first connector to the second connector, the output element being adjustable to vary a clamping force between the first region and the second region, thereby adjusting a position of the output element relative to the disc plane.

According to another aspect of the present invention there is provided an actuator including
a housing,
a piezo electric disc having a first side and a second side and defining an outer rim,
an elastomeric mount,
wherein the outer rim is received in the housing and the elastomeric mount engages the first side proximate the outer rim and engages the second side proximate the outer rim to mount the outer rim to the housing.

The invention will now be described, by way of example only, with respect to the accompanying drawings in which:—

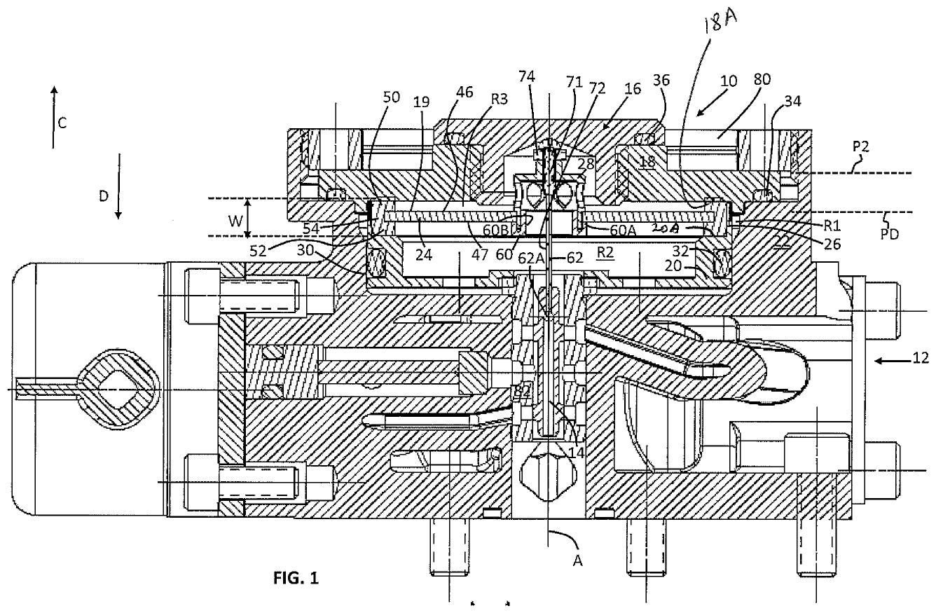

FIG. 1 shows a cross-section view of an actuator according to the present invention connected to a spool of a spool valve,

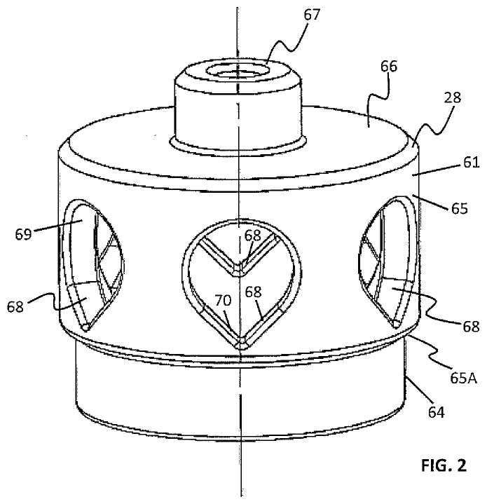

FIG. 2 shows an isometric view of part of FIG. 1,

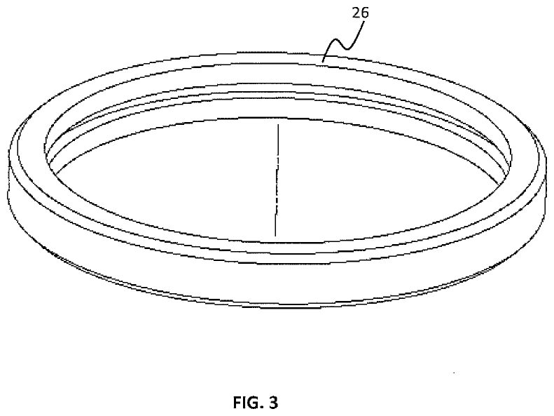

FIG. 3 shows a modified isometric view of certain parts of FIG. 1,

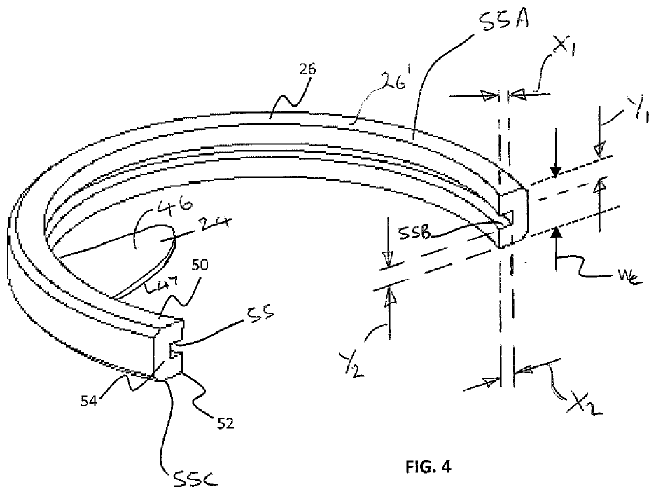

FIG. 4 shows a sectioned view of FIG. 3,

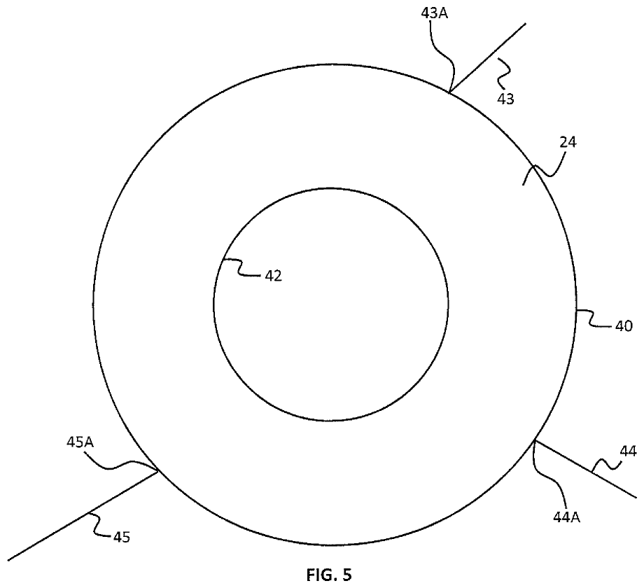

FIG. 5 shows a plan view of one of the components of FIG. 1,

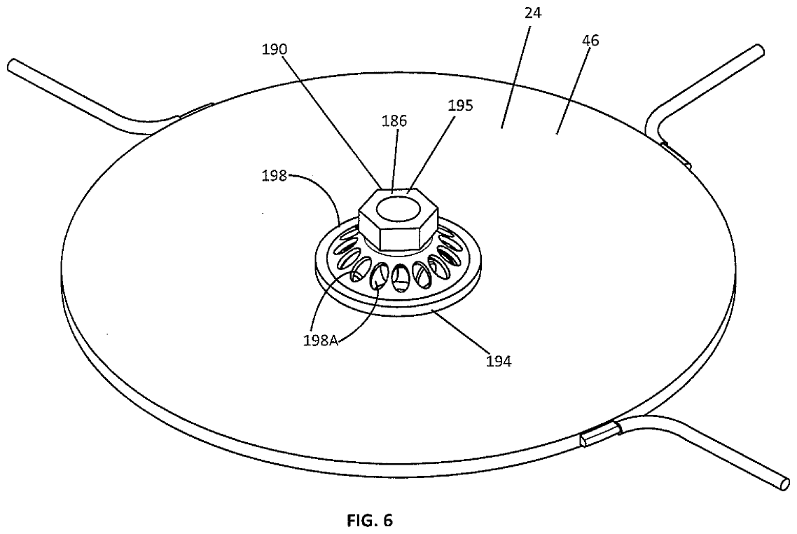

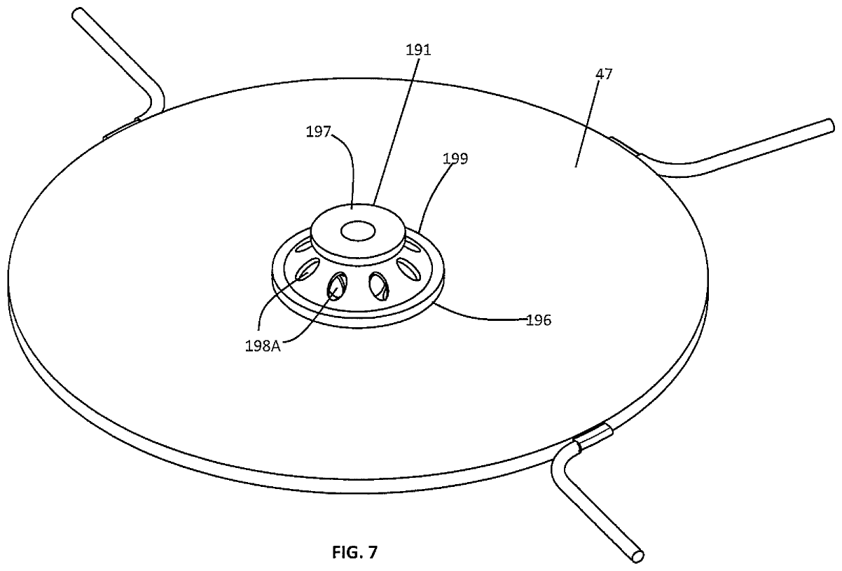

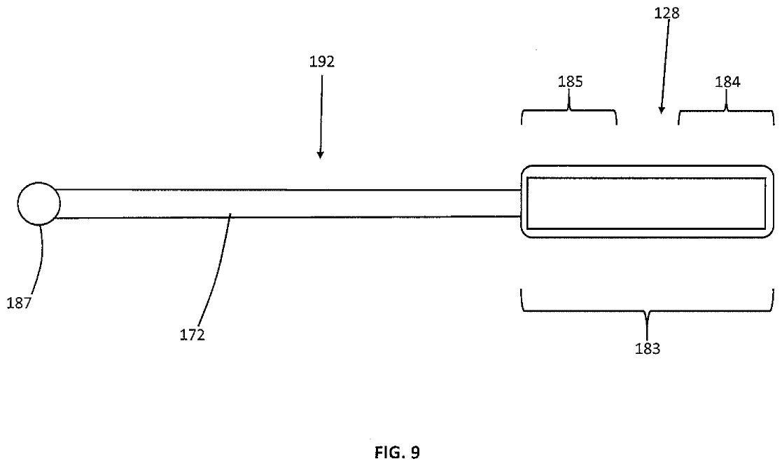

FIGS. 6 to 9 show various views of various components of an alternative actuator output.

With respect to FIGS. 1 to 5 there is shown an actuator 10 for actuating a spool 14 of a spool valve 12. The actuator 10 includes cap 16, first housing 18, second housing 20 and third housing 22. Third housing 22 acts to house certain of the actuator components, and also acts to house certain of the spool valve components. The actuator also includes a piezo electric disc 24, an elastomeric seal 26 and an actuator output 28.

The third housing 22 includes a recess 30 for receiving the second housing 20 and receiving a part of the first housing 18. An O-ring seal 32 seals the second housing to the recess 30 of the third housing 22. An O-ring seal 34 seals the first housing 18 to the third housing 22. Fixings, in this case screw ring 80, secure the first housing 18 to the third housing 22 thereby securing the second housing 20 in place.

Cap 16 is screw threaded into the first housing 18. An O-ring seal 36 seals the cap 16 to the first housing 18.

As best seen in FIG. 5, the piezo electric disc 24 is circular having an outer rim 40. The piezo electric disc 24 has a central circular hole which defines an inner rim 42. The piezo electric disc has a first side 46 and a second side 47.

Connected to the outer rim are electrical wires 43, 44 and 45. Applying appropriate voltages to the piezo electric disc via the electrical wires in a known manner causes the disc to dome either upwardly or downwardly when viewing FIG. 1. In one example, one wire may be +100 V, the other wire may be −100 V, and a third wire may be a variable voltage. An example of such a piezo electric disc is a piezo electric bimorph.

The elastomeric seal (see FIG. 3) is circular and, as best seen in FIG. 4, has a U-shaped cross section with a first arm 50 connected to the second arm 52 by a connecting region 54.

The actuator output includes a coupling part 60, a breather portion 61 (best seen in FIG. 2) and an output element 62.

The breather portion has a region 64, a cylindrical portion 65, a planar portion 66 and a boss 67.

The boss 67 is internally threaded and is positioned on the centre of the planar portion 66. The cylindrical portion 65 connects the planar portion 66 to the internally threaded region 64. Positioned within the cylindrical portion 65 are six holes 68.

Each hole is tear drop in shape, having an arcuate portion 69 that subtends approximately 270° and an acute portion 70. The acute portion 70 is proximate the internally threaded regions 64, whereas the arcuate portion 69 is proximate the boss 67.

The output element 62 includes a threaded portion 71 and an elongate rod 72 fixedly connected to the threaded portion 71. The actuator output 28 further includes a lock nut 74.

The actuator and spool valve are assembled as shown in FIG. 1. Note that the width W of the elastomeric seal as shown in FIG. 1 is shown in its non-compressed shape. The surface 19 of the first housing 18 in contact and adjacent elastomeric seal 26 is flat, and as such, FIG. 1 gives an indication of the amount of compression of the elastomeric seal when finally installed.

As can be seen from FIG. 1, the outer rim 40 of the piezo electric disc 24 is received in a housing defined by the first housing 18 and the second housing 20. In particular, the outer rim 40 is received in the elastomeric seal 26. The first arm 50 of the elastomeric seal engages the first side 46 and also engages the first housing 18 thereby sealing the first side to the first housing 18. The second arm 52 of the elastomeric seal engages the second side 47 proximate the outer rim to seal the second side to the second housing 20.

The third housing 22, second housing 20, and first housing 18 collectively define a first region R1 which is annular. Because O-ring seal 32 seals the second housing to the third housing, and because the elastomeric seal seals the second housing 20 to the piezo electric disc 24 and also seals the first housing 18 to the piezo electric disc 24 and because the O-ring seal 34 seals the first housing to the third housing 22, then it will be appreciated that the annular first region R1 is sealed with respect to a region R2 proximate the centre of the piezo electric disc on the second side 47. It will also be appreciated that the first annular region R1 is sealed with respect to region R3 proximate the centre of the piezo electric disc and on the first side 46.

As shown in FIG. 5, the electrical wires 43, 44 and 45 are connected at connection points 43A, 44A and 45A to the outer rim 40 of the piezo electric disc 24. Holes, slits or the like in the connection region 54 of the elastomeric seal 26 allow the wires to be connected to the piezo electric device. The wires are received in the first region R1, which, as explained above, is sealed from region R2 and R3. Therefore any fluid, such as hydraulic oil or the like, in region R2 or R3 is sealed from region R1 and therefore will not come into contact with the electrical wires 43, 44 or 45, nor will it come in contact with the connection of those wires to the piezo electric disc. The connection 43A, 44A and 45A may be made by soldering or the like. Fluids, such as hydraulic oil or the like, can be corrosive and can attack the insulation of electrical wires and can also attack connections such as soldering or the like. Advantageously by ensuring region R1 is sealed from regions R2 and R3, fluids, such as hydraulic oil in regions R2 and R3 will not come into contact with the connections or the wires in region R1.

As best seen in FIG. 1, the actuator output 28 is connected to the central part of the piezo electric disc by epoxy gluing the coupling part 60, inner rim 42 and the region 64 together and thereby fixing a region of the piezo electric disc proximate the inner rim 42 between a shoulder 65A of the cylindrical portion 65 of the breather portion 61 and a shoulder 60A of the coupling part 60.

The threaded portion 71 of the output element is threadably engaged in boss 67 so that the output element 62 projects through a plane PD defined by the piezo electric disc 24. The threaded portion 71 can be adjusted, and once properly adjusted the lock nut 74 can be tightened thereby fixably connecting the breather portion to the output element.

An end 62A of the output element 62 is connected to the spool 14 which is slidably received in bushing 82. Bushing 82 is fixably received in the third housing 22. Ports in the bushing 82 correspond with ports in the third housing 22.

Operation of the actuator is as follows:—

As shown in FIG. 1 the piezo electric disc is flat. By applying appropriate voltages via wires 43, 44 and 45 the piezo electric disc 24 will distort into a dome shape and the inner rim 42 will move, in one example, downwardly when viewing FIG. 1 relative to the outer rim 40. As the inner rim 42 moves downwardly, so to does the actuator output 28, thus causing end 62A of the output element to move downwardly thereby causing the spool 14 to move downwardly relative to the bushing 82 and third housing 22. Movement of the spool connects and/or isolates various passages within spool valve 12 in a manner known in the art.

As the inner rim 42 moves downwardly, then the volume of region R3 in the housing above the piezo electric disc adjacent the first side 46 increases. Region R2 and region R3 may be full of fluid, for example hydraulic oil, and the six holes 68 allow fluid to move from second region R2 to region R3 as the inner rim 42 move downwardly and allow hydraulic fluid in region R3 to move to region R2 as the inner rim 42 moves upwardly.

It should be noted that the output element 62 is connected to the breather portion 61 at a plane P2. The plane P2 is spaced apart from the plane PD of the piezo electric disc 24.

It should be noted that the breather portion 61 performs two functions. Firstly it couples the inner rim 42 to the output element 62, and it also allows the flow of fluid between regions R2 and R3. By spacing the plane at which the breather portion is connected to the output element (plane P2) from the plane of the piezo electric disc (PD) this allows the total cross section area of the holes 68 to be similar or larger than the total cross section area defined between the inner bore 60B and the diameter of the output element 62 in plane PD. In other words, the total cross section area of the six holes 68 can be similar to or greater than the area defined by (π ((diameter of inner bore 60B)²−(diameter of output element 62)²)/4). By connecting the breather portion to the output element at a plane remote from the plane of the piezo electric disc allows the holes in the breather portion to be relatively “tall”, and thereby having a relatively large cross section (by virtue of their tallness) without having to weaken the breather portion, thereby ensuring that it can fulfil its function of connecting the output element 62 to the inner rim 42 of the piezo electric disc. In one example, the total cross section area of the holes may be 16 mm² and the total cross section area defined between inner bores 60B and the diameter of the output element 62 in plane PD may be 12 mm².

The actuator may need to operate at high frequencies and therefore hysteresis can be reduced by ensuring free flow of hydraulic oil fluid between regions R2 and R3. This is achieved by arranging the minimum number of features in the hole defined by the inner ring 42 at the plane PD of the piezo electric disc. As can be seen from FIG. 1, the only features found in the plane PD in the hole defined by inner rim 42 are the elongate output element 62 and those features coupling the piezo electric disc to the breather portion 61. Accordingly, there is relatively little restriction to the flow of hydraulic oil through the hole defined by inner ring 42 in the plane of the disc PD. By connecting the breather portion to the output element at a plane remote from the plane of the piezo electric disc allows the total cross section area of the holes to be relatively large, and therefore the holes similarly do not cause any significant restriction to movement of oil between regions R2 and R3. Advantageously, hysteresis can be reduced in this manner.

As shown in FIGS. 1, 3 and 4 elastomeric seal is a single seal, though in further embodiments the appropriate sealing function could be performed by more than one seal.

As shown in FIG. 4 the seal as a U-shaped cross section, though in further embodiments alternative cross section shapes could be used.

As shown in FIG. 1, the piezo electric disc and seal are received in the housing defined by the first housing 18 and the second housing 20. In further embodiments the piezo electric disc and/or the seal could be received in a single housing or in more than two housings.

As shown in FIG. 1 the region R1 is defined by the first housing 18, the second housing 20 and the third housing 22. In further embodiments, such a sealed region could be defined by one or two or more than three housings.

As shown in FIG. 1 the actuator output comprises the coupling part 60, the breather portion 61, the output element 62. In further embodiments, the actuator output could comprise a single integral component, or two components or more than three components.

As shown in FIG. 1 the output element 62 includes threaded portion 71 and an elongate rod 72. In further embodiments the output element 62 could comprise a single component or could comprise more than two components.

As shown in FIG. 1 the output element extends through the plane PD of the piezo electric disc 24. In further embodiments the output element 62 need not extend through the plane PD, in other words the coupling part 60 and breather portion 61 could be mounted “upside down” when compared with FIG. 1 whereby the output element 62 would then only extend away (downwardly) from the plane of the piezo electric disc.

As shown in FIG. 2, the holes 68 are tear drop shaped. In further embodiments alternatively shaped holes including circular could be used. As shown in FIG. 2 there are six holes 68. In further embodiments more than six holes could be used or less than six holes could be used.

Depending upon any fluids within the actuator, then the elastomeric ring (or elastomeric seal, or elastomeric mount (see below)) may be made from appropriate materials. For example, the elastomeric ring may be made from EPR or EPDM for phosphate ester fluids, fluorocarbon or fluorsilicone for aero engine fuel applications and buna or nitrile for mineral oil applications.

A further advantage of an elastomeric seal is that it enables the actuator to have a longer stroke when compared with an actuator having a piezoelectric disc which is more rigidly mounted at its outer rim. Thus, a piezoelectric disc rigidly mounted at its outer rim tends to cause the rim of the disc to remain relatively flat and planar as the inner region of the piezoelectric disc becomes domed. By using an elastomeric seal all of the piezoelectric disc, including the outer edge can become domed and this extends stroke of the actuator. Thus with an elastomeric seal the outer edge of the disc is relatively free to “tilt” as the piezoelectric disc becomes domed.

With reference to FIGS. 6 to 9 there is shown the piezo electric disc 24 together with an alternative actuator output 128. The actuator output 128 primarily includes a first connector 190, a second connector 191 and an output element 192. The first connector 190 has a first region 194 for engaging the piezo electric disc 24 on the first side 46. The first connector also has a first portion in the form of shoulder 195. The shoulder surrounds a central hole 186.

The second connector 191 has a second region 196 which engages the piezo electric disc 24 on the second side 47. The second connector also has a second portion in the form a threaded hole 197.

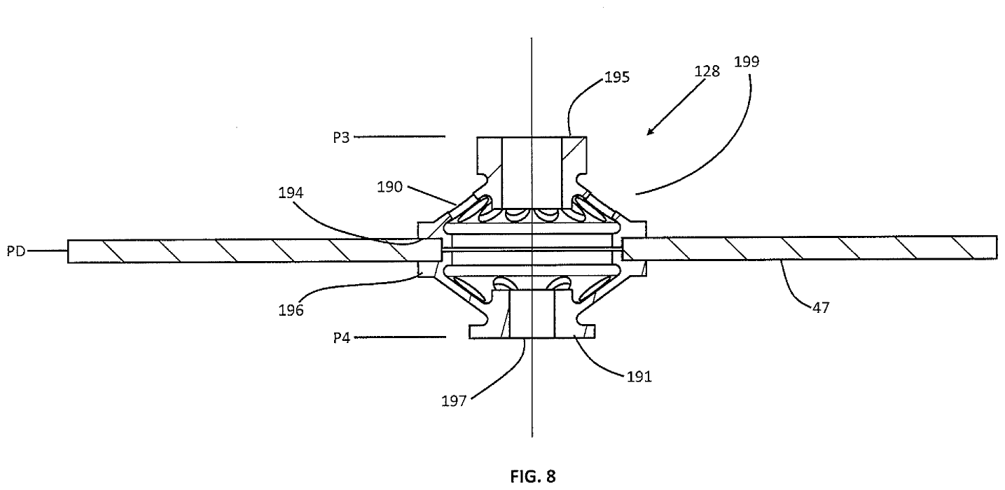

As best seen in FIG. 8, the first portion 195 lies in plane P3 which is spaced apart from the plane P4 in which the threaded hole 197 lies. In this example the plane P3 is spaced apart from the piezo electric disc plane PD as is plane P4. The first connector 190 includes a breather portion 198 having a plurality of breather holes 198A. The second portion 191 has a breather portion 199 having a plurality of breather holes 199A.

The output element 192 has a threaded portion 183 which forms a first threaded portion 184 and second threaded portion 185. Extending from the threaded portion 183 is a elongate rod 172 (which performs the same function as rod 72 shown in FIG. 1).

The diameter of the threaded portion 183 is a clearance fit in the central hole 186 of the first connector 190.

The actuator output 128 is assembled onto the piezo electric disc 124 as follows:—

The first connector 190 is positioned as shown in FIG. 8 such that the first region 194 engages the piezo electric disc on the first side 46. The second connector 191 is positioned as shown in FIG. 8 such that the second region 196 engages the piezo electric disc on the second side 47. The output element 192 has the elongate rod 172 passed through central hole 186 of the first connector and then through the threaded hole 197 until the second threaded portion 185 engages with the threads of the threaded hole 197. The output element 192 is then screwed into the threaded hole 197 until the end 187 of the elongate rod 172 is positioned approximately at the correct distance from the plane PD. When so positioned, the first threaded portion 184 will project from the central hole 186. A lock nut (74) is then threaded onto the first threaded portion 84 until it engages shoulder 195 whereupon it is tightened to a first torque so as to ensure that end 187 is held in its correct a proximate position relative to plane PD.

The end 187 is connected to spool 14. The sub assembly comprising the actuator output 128, piezo electric disc 124 and spool 14 can then be fitted with the elastomeric seal 26, and inserted into the third housing 22 such that the spool 14 sits in bushing 82 and the first housing 18 (excluding cap 16) can be secured in place. Under these circumstances end 187 will be in approximately its correct position, and hence spool 14 will be in approximately its correct axial position.

The axial stiffness (when considering axis A (see FIG. 1)) of the first connector 190 is different to the axial stiffness of the second connector 191. For the purposes of this example, assume the axial stiffness of the first connector 190 is twice the axial stiffness of the second connector 191. If during initial assembly it is determined that the spool 14 is positioned too low (when considering FIG. 1) i.e. too far in the direction of arrow D in the housing 22, then tightening the lock nut of the actuator output 128 will cause the first portion 195 to move downwards (i.e. in the direction of arrow D of FIG. 1) and will cause the second portion 197 to move upwards (i.e. in the direction of arrow C of FIG. 1). However, due to the different stiffness of the first connector and the second connector, the second portion 197 will move upwards in the direction of arrow C more than the first portion 195 moves downwards in the direction of arrow D. Consequently, by tightening the lock nut of the actuator output 128 end 187 and hence spool 14 can be adjusted upwardly. Conversely, if it is determined, upon initial assembly, that spool 14 as connected to the actuator output 128 is too high when considering FIG. 1, then it can be lowered, i.e. moved in the direction of arrow D by loosening the lock nut of the actuator output 128.

Once the spool has been correctly adjusted by tightening or loosening the lock nut, then the cap 16 can be replaced.

As will be appreciated, by having a first connector and a second connector with different axial stiffnesses allows for fine adjustment of the position of the spool 14. The first connector and second connector both have breather portions which function similar to the breather portions of FIG. 2.

In an alternative embodiment if the axial stiffness of the second connector is stiffer than that of the first connector, then tightening of a lock nut will cause the spool to move downwards, whereas loosening of a lock nut will cause the spool to move upwards.

The second threaded portion 185 allows for “coarse” adjustment of the output element 192 relative to the second connector 191, and the subsequent tightening or loosening of a lock nut allows for “fine” adjustment. In further embodiments such coarse adjustment may not be required, in which case the second threaded portion 185 could be replaced with a shoulder which abuts an edge of hole 197, which therefore need not be threaded.

Similarly, in alternative embodiments adjustments could be provided via threaded portion 184 engaging a threaded hole of the first connector 190.

As shown in FIG. 8, the plane P3 of the first portion 195 is spaced from plane PD, but in further embodiments this need not be the case. As shown in FIG. 8 the plane P4 of the second portion 197 is spaced from plane PD, but further embodiments this need not be the case. In order for “fine” adjustments to take place, then all that is necessary is to have differing axial stiffness and be able to move the plane of the first portion 195 axially relative to the plane P4 of the second portion 197.

As shown in FIG. 8, the plane P3 of the first portion is on the first side 46, though in further embodiments this need not be the case. As shown in FIG. 8 the plane P4 of the second portion 197 is on the second side 47, though in further embodiments this need not be the case.

As mentioned above, an advantage of an elastomeric seal is that it provides for a greater actuator travel since the outer edge of the disc is free to “tilt” as the piezoelectric disc becomes domed.

This advantage is not restricted to elastomeric seals. An elastomeric mount (which may or may also act as a seal) can also utilise this advantage. Thus, the elastomeric seal 26 shown in FIG. 4 is an example of an elastomeric mount 26′. Design considerations of an elastomeric mount are to provide sufficient flexibility so as to allow the outer circumferential edge of the piezoelectric disc to “tilt” thereby increasing the actuation travel, but for the elastomeric mount to remain sufficiently rigid such that the disc as a whole does not move axially. Thus, the various dimensions of the elastomeric mount, how the elastomeric mount is clamped within the housing, and how the elastomeric mount clamps the piezoelectric disc become important. Consideration of FIG. 4 shows the elastomeric mount 26′ in a clamped condition, i.e. the dimensions shown in FIG. 4 are dimensions the elastomeric mount 26′ would adopt when installed in the housing of FIG. 1 and when holding the piezoelectric disc of FIG. 1. FIG. 4 shows part of the piezoelectric disc 24 and also shows the first side 46 and second side 47 of the piezoelectric disc 24. As will be appreciated the first side 46 of the piezoelectric disc engages a first engagement surface 55 of the mount 26′. The first engagement surface 55 has a radial dimension X₁. The housing (in this case the first housing 18) has a first support surface 18A (see FIG. 1) situated on the first side 46 of the piezoelectric disc which support surface 18A engages the elastomeric mount at a second engagement surface 55A. Thus, the first support surface 18A is opposite that part of the first side 46 of the piezo electric disc which engages the first engagement surface 55 of the elastomeric mount 26. The first engagement surface 55 faces in an opposite direction to the second engagement surface 55A.

The first engagement surface 55 of the elastomeric mount is spaced from the second engagement surface 55A of the elastomeric mount by an axial distance Y₁.

Increasing dimension X₁ tends to restrict the tipping of the edge of the piezoelectric disc, but reducing distance X₁ reduces the bearing surface area between the disc and the mount and therefore the long term durability of the mount in this region. Increasing distance Y₁ tends to allow the edge of the disc to tilt more, but also tends to allow the disc as a whole to move axially more. Conversely reducing the dimensions Y₁ tends to restrict tilting of the edge of the piezoelectric disc, but nevertheless reduces axial movement of the disc as a whole. As shown in FIG. 1, X₁ is approximately equal to Y₁ and as such the ratio of the radial dimension to the axial dimension in this example is approximately 1. However, X₁ can be smaller than Y₁, for example the ratio of the radial dimension and axial dimension could be 10%, i.e. dimension Y₁ is ten times larger than dimension X₁. Alternatively dimension X₁ could be greater than dimension Y₁. The ratio of the radial dimension to axial dimension could be 400%, i.e. dimension X₁ could be 4 times larger than dimension Y₁. In exemplary embodiments, the ratios of the radial dimension to axial dimension may be greater than 10%, or greater than 50%, or greater than 70%, or less than 400%, or less than 200%, or less than 100%.

As shown in FIG. 4 the second side 47 of the piezoelectric disc engages a third engagement surface 55B of the mount 26′. The third engagement surface 55B has a radial dimension X₂. The housing (in this case the second housing 20) has a second support surface 20A (see FIG. 1) situated on the second side 47 of the piezoelectric disc which support surface 20A engages the elastomeric mount at a fourth engagement surface 55C. Thus, the second support surface 20A is opposite that part of the second side 47 of the piezoelectric disc which engages the third engagement surface 55B of the elastomeric mount 26′. The third engagement surface 55B faces in a opposite direction to the fourth engagement surface 55C. The third engagement surface 55B of the elastomeric mount is spaced from the fourth engagement surface 55C of the elastomeric mount by an axial distance Y₂.

Varying dimensions X₂ and Y₂ has an analogous effect to varying distances X₁ and Y₁ as described above.

For a particular elastomeric mount the ratio of the first radial dimension X₁ to first axial dimension Y₁ may be substantially the same as the ratio of the second radial dimension X₂ to second axial dimension Y₂. In such an embodiment, the performance of the actuator when piezoelectric disc becomes domed in a concave manner may be substantially the same as the performance when the piezoelectric disc becomes domed in a convex manner.

In further embodiments the ratio of the first radial dimension X₁ to first axial dimension Y₁ may be different from the ratio of a second radial dimension X₂ to second axial dimension Y₁. Under these circumstances the piezoelectric disc may perform differently when domed in a concave manner when compared to doming in a convex manner.

As mentioned above, the elastomeric seal or elastomeric mount may be made from various materials including various synthetic rubber materials.

Examples of materials which the elastomeric seal or elastomeric mount may be made from are as follows:

| Elastomer description | ISO1629 Abbreviation |
|---|---|
| Fluorocarbon Rubber | FKM |
| Fluorosilicone Rubber | FMVQ |
| Nitrile rubber | NBR |
| Ethylene Propylene Diene | EPDM |
| Monomer | |

Any of the piezoelectric discs described above may be piezoelectric bimorphs.

1. An actuator comprising:
a housing,
a piezo electric disc having a first side and a second side and defining an outer rim,
an elastomeric seal,
wherein the outer rim is received in the housing and the elastomeric seal engages the first side proximate the outer rim to seal the first side to the housing, the elastomeric seal engages the second side proximate the outer rim to seal the second side to the housing.

2. An actuator as defined in claim 1 wherein the seal is a single seal.

3. An actuator as defined in claim 2 wherein the seal has a U-shaped cross section.

4. (canceled)

5. An actuator as defined in claim 1 wherein the seal is received in the housing, the seal and housing thereby defining a first sealed region sealed from a region proximate the centre of the piezo electric disc.

6. An actuator as defined in claim 5 including at least one electrical connection on the outer rim, the electrical connection being defined in the first sealed region.

7. An actuator as defined in claim 6 wherein the electrical connection includes at least one electrical wire, the electrical wire being at least partially received in the first sealed region, the seal has a U-shaped cross section, and the U-shaped cross section is defined by a first arm portion connected to a second arm portion by a connecting region, the connecting region including a hole to receive the electrical wire.

8. (canceled)

9. An actuator comprising:
a housing,
a piezo electric disc having a first side and a second side defining an outer rim, an inner rim, and a disc plane,
the piezo electric disc being mounted proximate the outer rim in the housing for movement of the inner rim relative to the outer rim during actuation,
the actuator further including an actuator output defining a breather portion and an output element, the output element being fixedly connected to the breather portion at a coupling plane, the coupling plane being spaced apart from the disc plane,
the breather portion being fixedly connected to the piezo electric disc proximate the inner rim at the disc plane,
the breather portion having a plurality of holes to allow fluid to move from the first side to the second side and from the second side to the first side.

10.-13. (canceled)

14. An actuator as defined in claim 9 wherein the plurality of holes collectively have a first total open area and the actuator output defines a second total open area at the disc plane and the first total open area is at least 80% of the second total open area.

15.-18. (canceled)

19. An actuator as defined in claim 9, wherein the output element is connected to a hydraulic spool.

20. An actuator comprising:
a housing,
a piezo electric disc having a first side and a second side defining an outer rim, an inner rim, and a disc plane,
the piezo electric disc being mounted proximate the outer rim in the housing for movement of the inner rim relative to the outer rim during actuation,
a first connector having a first region engaging the piezo electric disc on the first side and a first portion for reacting against an output element, the first connector defining a first stiffness between the first region and the first portion,
a second connector having a second region engaging the piezo electric disc on the second side and a second portion for reacting against the output element, the second connector defining a second stiffness between the second region and the second portion,
the first portion being spaced from the second portion, and
the first stiffness being different from the second stiffness, and
an output element connecting the first connector to the second connector, the output element being adjustable to vary a clamping force between the first region and the second region, thereby adjusting a position of the output element relative to the disc plane.

21.-28. (canceled)

29. An actuator as defined in claim 20 wherein the first portion defines a first portion plane, the first portion plane being spaced apart from the disc plane, the first connector including a breather portion having a plurality of holes to allow fluid to move from the first side to the second side and from the second side to the first side.

30. An actuator as defined in claim 20 wherein the second portion defines a second portion plane, the second portion plane being spaced apart from the disc plane, the second connector including a breather portion having a plurality of holes to allow fluid to move from the first side to the second side and from the second side to the first side.

31. An actuator as defined in claim 9 further including an elastomeric seal, wherein the outer rim is received in the housing and the elastomeric seal engages the first side proximate the outer rim to seal the first side to the housing, and the elastomeric seal engages the second side proximate the outer rim to seal the second side to the housing.

32. An actuator as defined in claim 9 further including an elastomeric mount, wherein the outer rim is received in the housing and the elastomeric mount engages the first side proximate the outer rim, and engages the second side proximate the outer rim to resiliently mount the outer rim to the housing.

33. An actuator comprising:
a housing,
a piezo electric disc having a first side and a second side and defining an outer rim,
an elastomeric mount,
wherein the outer rim is received in the housing and the elastomeric mount engages the first side proximate the outer rim and engages the second side proximate the outer rim to mount the outer rim to the housing.

34.-35. (canceled)

36. An actuator as defined in claim 33 wherein the first side of the piezoelectric disc engages a first engagement surface of the elastomeric mount, the first engagement surface having a first radial dimension (X₁) in engagement with the first side, the housing having a first support surface on the first side of the piezoelectric disc for engaging a second engagement surface of the elastomeric mount, the first engagement surface being axially spaced from the second engagement surface by a first axial dimension (Y₁), the ratio of the first radial dimension to first axial dimension being greater than 10%.

37. An actuator as defined in claim 36 wherein the ratio is less than 400%.

38. An actuator as defined in claim 36 wherein the second side of the piezoelectric disc engages a third engagement surface of the elastomeric mount, the third engagement surface having a second radial dimension (X₂), the housing having a second support surface on the second side of the piezoelectric disc for engaging a fourth engagement surface of the elastomeric mount, the third engagement surface being axially spaced from the fourth engagement surface by a second axial dimension (Y₂), the ratio of the second radial dimension to second axial dimension being greater than 10%.

39. An actuator as defined in claim 38 wherein the ratio of the second radial dimension to second axial dimension is less than 400%.

40. An actuator as defined in claim 1 wherein the elastomeric mount is made from a synthetic rubber.

41. (canceled)
